(19) United States
(12) Patent Application Publication
(10) Pub. No.: US 2009/0093124 A1
(43) Pub. Date: Apr. 9, 2009

(54) Method of manufacturing semiconductor device

(75) Inventor: Shin Hiyama, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/230,676

(22) Filed: Sep. 3, 2008

(30) Foreign Application Priority Data
Oct. 4, 2007 (JP) 2007-260569

(51) Int. Cl. H01L 21/302; H01L 21/306

(52) U.S. Cl. 438/710; 156/345.29; 257/E21.214

(57) ABSTRACT

To provide a method of manufacturing a semiconductor device, which includes a process capable of excellently removing a photoresist in which a high dose of ion is implanted. A photoresist with a high dose of ion implanted therein is removed from a wafer through a first removing process for carrying out a plasma process of at least a reaction gas including oxygen molecules and hydrogen molecules to remove an organic component in the photoresist from the wafer and a second removing process for carrying out a plasma process of at least a reaction gas including hydrogen molecules following the first removing process to remove a dopant deposit from the wafer.

### BACKGROUND OF THE INVENTION

1. Technical Field

The present invention relates to a method of manufacturing a semiconductor device, the method including a removing process for removing a photoresist in which high dose ion is implanted from a substrate.

2. Related Art

There has been known a method of manufacturing a semiconductor device, which includes a removing process that removes a photoresist (a photoresist film) used as a pattern mask by dry removing, wherein in the removing process a substrate is loaded into an air-tight treating chamber, a plasma source provided in an upper part of the treating chamber, for example, is supplied with a reaction gas while high frequency power is applied to generate plasma, and reactive active species (a radical) generated in the plasma is used to remove the photoresist on the substrate by oxidization and vaporization. In the technology, typically used is an O₂ gas or a reaction gas mainly including O₂ since the photoresist is an organic film (Patent Reference 1, for example).

Patent Reference 1: JP-A 2003-77893

Using the O₂ gas or the reaction gas mainly including O₂ to remove the photoresist which has been used as a mask in a process of implantation of an ion in the substrate allows an organic component of the photoresist to be removed, however, it has a problem as follows: a high dose of ion has been implanted in the photoresist in the process of implantation of the ion in the substrate, but sufficiently removing a dopant such as P (phosphorus), As (arsenic) and Br (bromine) which has been implanted in the photoresist is difficult since an oxide of the dopant is low volatile. Further, there is a problem that extremely long processing time is required even in the case that the dopant can be removed.

The dopant and the oxides thereof deposited on the substrate can be removed by wet cleaning after removing the photoresist. This, however, causes a new problem that a cleaning liquid must be exchanged more frequently since the cleaning liquid is used for cleaning the dopant and the oxides thereof.

### SUMMARY OF THE INVENTION

An object of the invention is to provide a method of manufacturing a semiconductor device, which includes a removing process capable of excellently removing a photoresist in which a high dose of ion is implanted.

A characteristic of the invention is a method of manufacturing a semiconductor device including a removing process that removes from a substrate a photoresist having a high dose of ion implanted, wherein the removing process including: a first removing process for carrying out a plasma process of a reaction gas including at least oxygen molecules and hydrogen molecules to remove an organic component in the photoresist of the substrate; and a second removing process for carrying out a plasma process of a reaction gas including at least hydrogen molecules following the first removing process to remove a dopant deposit from the substrate.

In accordance with the invention, provided can be a method of manufacturing a semiconductor device, which includes a removing process capable of excellently removing a photoresist in which a high dose of ion is implanted.

### BRIEF DESCRIPTION OF THE DRAWINGS

The invention will be described with reference to the accompanying drawings, wherein like numbers reference like elements, and wherein:

FIG. 1 schematically shows a horizontal sectional view illustrating an apparatus for removing photoresist in accordance with a preferred embodiment of the invention;

FIG. 2 schematically shows a vertical sectional view illustrating an apparatus for removing photoresist in accordance with a preferred embodiment of the invention;

FIG. 3 schematically shows a vertical sectional view illustrating an apparatus for removing photoresist in accordance with a preferred embodiment of the invention; and

FIG. 4 is a sectional view showing a process chamber used in an apparatus for removing photoresist in accordance with a preferred embodiment of the invention.

### DETAILED DESCRIPTION OF THE EMBODIMENTS

Then, a preferred embodiment of the invention is described in detail with reference to the drawings. In the preferred embodiment of the invention, a method of manufacturing a semiconductor device is achieved by means of an apparatus for removing photoresist used as apparatus for manufacturing a semiconductor.

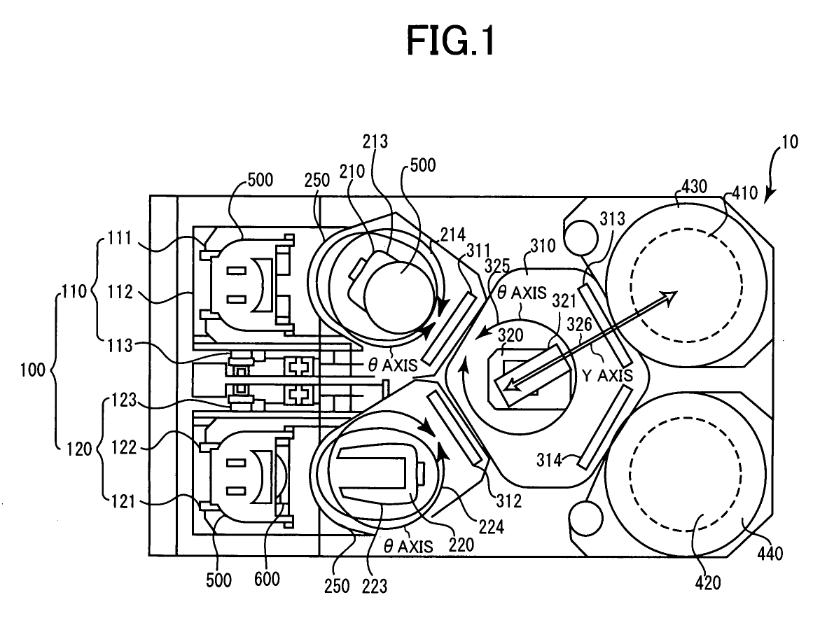

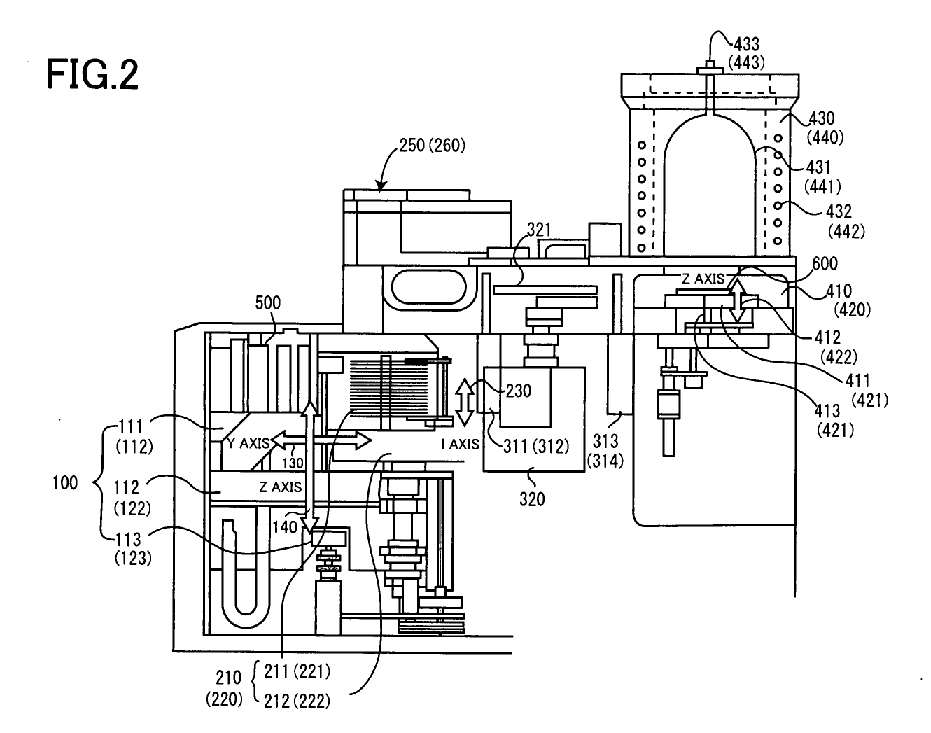

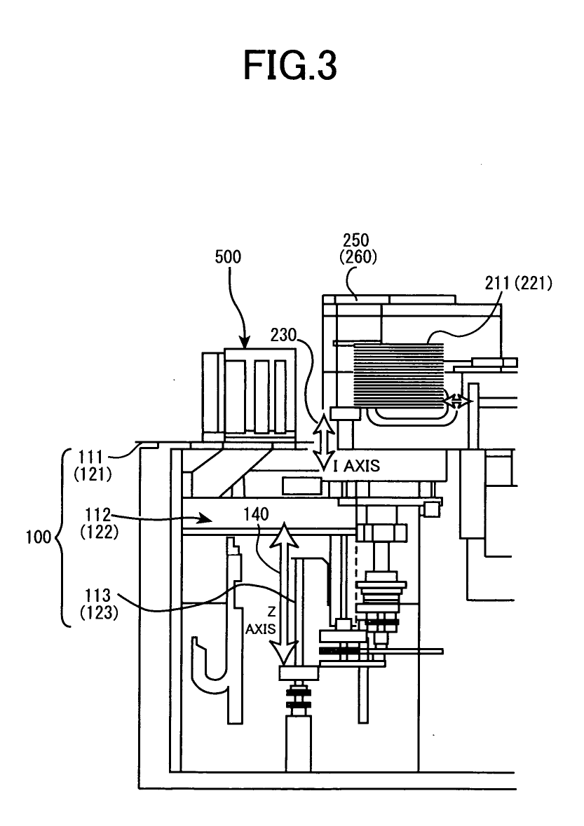

FIG. 1 shows a horizontal sectional view illustrating an apparatus for removing photoresist in accordance with the preferred embodiment of the invention. FIGS. 2 and 3 show vertical sectional views illustrating the apparatus for removing photoresist in accordance with the preferred embodiment of the invention. As shown in FIGS. 1 and 2, an apparatus for removing photoresist 10 includes a cassette transfer part 100, a load lock chamber part 200, a transfer module part 300 and a process chamber part 400 used as a treating chamber in which an removing process is carried out.

The cassette transfer part 100 includes cassette transfer units 110 and 120 used as a first transfer part. The cassette transfer units 110 and 120 respectively have cassette tables 111 and 121 on which cassettes 500 holding wafers 600 used as substrates are placed and Y axis assemblies 112 and 122 and Z axis assemblies 113 and 123, which respectively let a Y axis 130 and a Z axis 140 of the cassette tables 112 and 121 operate.

The load lock chamber part 200 includes load lock chambers 250 and 260 and buffer units 210 and 220 respectively receiving the wafers 600 from the cassettes 500 placed on the cassette tables 111 and 121 to hold the respective wafers 600 in the load lock chambers 250 and 260. The buffer units 210 and 220 have buffer finger assemblies 211 and 221 and index assemblies 212 and 222 below the buffer finger assemblies 211 and 221. The buffer finger assembly 211 (221) and the index assembly 212 (222) below the buffer finger assembly 211 (221) simultaneously rotate in the direction of a θ axis 214 (224).

The transfer module part 300 includes a transfer module 310 used as a transfer chamber. The load lock chambers 250 and 260 are mounted to the transfer module 310 through the gate valves 311 and 312. The transfer module 310 is provided with a vacuum arm robot unit 320 used as a second transfer part.

The process chamber part 400 includes process chambers 410 and 420 used as treating chambers and plasma generating chambers 430 and 440 provided above the process chambers 410 and 420. The process chambers 410 and 420 are mounted to the transfer module 310 through the gate valves 313 and 314.

The process chambers 410 and 420 include susceptor tables 411 and 421 on which the wafers 600 are placed. Lifter pins 413 and 423 are provided so as to pass through the susceptor tables 411 and 421, respectively. The lifter pin 413 moves up and down in the directions of the Z axes 412 and 422.

The plasma generating chambers 430 and 440 include reaction case 431 and 441, respectively. Outside the reaction case 431 and 441, provided are resonance coils 432 and 442. High frequency power is applied to the high frequency coils 432 and 442 to be transmuted plasma state (carry out a plasma process) a reaction gas for an removing process which is introduced from the gas introducing ports 433 and 443, into plasma. The plasma is used for removing the photoresist on the wafers 600 placed on the susceptor tables 411 and 421.

In the apparatus for removing photoresist 10 having the structure described above, the wafer 600 is carried from the cassette table 111 (121) to the load lock chamber 250 (260). At that time, the cassette 500 is first loaded on the cassette table 111 (121) and the Z axis 140 operates downward, as shown in FIGS. 2 and 3. The Y axis 130 of the buffer finger assembly 211 (221) moves to the direction of the cassette 500 with the Z axis 140 being maintained at a lower position. By the operation of an I axis 230 the buffer finger 213 (223) of the buffer finger assembly 211 (221) receives the 25 wafers 600 from the cassette 500. The Y axis 130 returns to its original position under the state that the buffer finger 213 (223) has received the wafers 600.

In the load lock chamber 250 (260), the wafer 600 held in the load lock chamber 250 (260) by means of the buffer unit 210 (220) is loaded onto a finger 321 of the vacuum arm robot unit 320. The vacuum arm robot unit 320 is rotated in the direction of θ axis 325. The finger is extended in the direction of Y axis 326 to load the wafer onto the susceptor table 411 (421) in the process chamber 410 (420).

Now, it will be described a process of loading the wafer 600 from the finger 321 to the susceptor table 411 (421).

Cooperation of the finger 321 of the vacuum arm robot unit 320 with the lifter pin 413 (423) causes the wafer 600 to be loaded onto the susceptor table 411 (421). The reverse operation causes the wafer 600 the treatment of which have been completed to be loaded from the susceptor table 411 (421) onto the buffer unit 210 (220) in the load lock chamber 250 (260) by means of the vacuum arm robot unit 320.

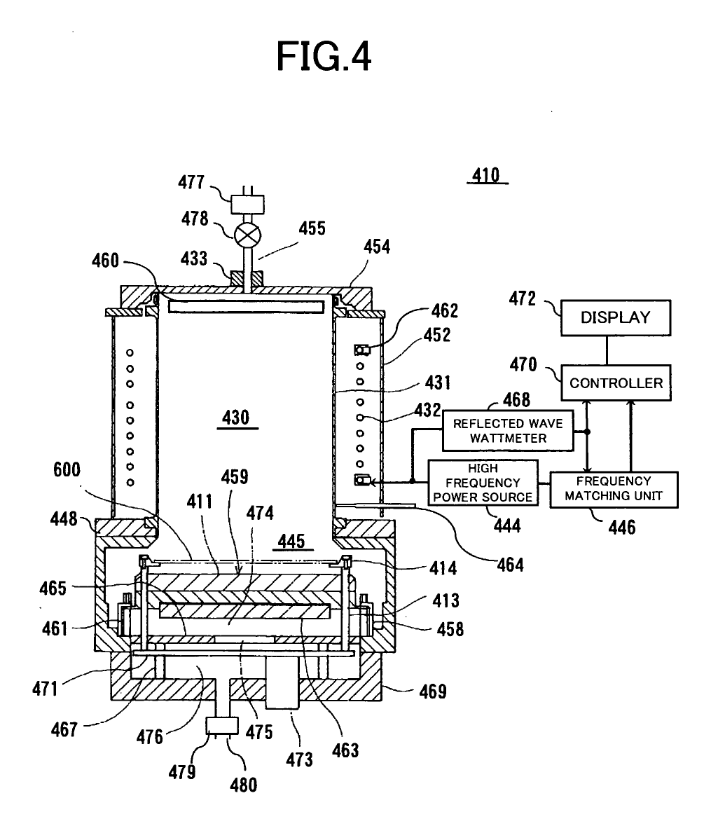

FIG. 4 shows the process chamber 410 in detail. The above-described process chamber 420 has the same as the process chamber 410.

The process chamber 410 is a high frequency electrodeless discharge type process chamber in which photoresist removing is performed for a semiconductor substrate or a semiconductor element in a dry process. The process chamber 410 includes the plasma generating chamber 430 for generating plasma, a treating chamber 445 containing the wafer 600 such as a semiconductor substrate, a high frequency power source 444 that supplies the plasma generating chamber 430 (particularly, the resonance coil 432) with the high frequency power and a frequency matching unit 446 that controls the oscillation frequency of the high frequency power supply 444, as shown in FIG. 4. The plasma generating chamber 430 is provided above a horizontal base plate 448 used as a pedestal and the treating chamber 445 is provided below the base plate 448 to form the process chamber 410, for example. The resonance coil 432 and an outer shield 452 form a spiral resonator.

The plasma generating chamber 430 has the reaction case 431, which is arranged to be capable of reduction in pressure and to which the reaction gas for the plasma is supplied, the resonance coil 432 wound around the outer circumference of the reaction case and the outer shield 452 which is provided in the outer circumference of the resonance coil 432 and electrically grounded.

The reaction case 431 is a so-called chamber generally formed from quartz glass or ceramic of high purity into the shape of a cylinder. The reaction case 431 is typically arranged so that its axis would be vertical. The upper and lower ends of the reaction case 431 are air-tightly sealed by a top plate 454 and the treating chamber 445. On the bottom surface of the treating chamber 445 below the reaction case 431, it is provided a susceptor 459 held by plural (four, for example) supports 461. The susceptor 459 has a substrate heating part 463 for heating the susceptor table 411 and a wafer on the susceptor.

An exhausting plate 465 is provided below the susceptor 459. The exhausting plate 465 is held on a bottom substrate 469 through a guide shaft 467. The bottom substrate 469 is air-tightly provided on the lower surface of the treating chamber 445. An up-and-down substrate 471 is provided so as to be able to freely rise and fall with the guide shaft 467 being used as a guide. The up-and-down substrate 471 holds at least three lifter pins 413.

The lifter pin 413 passes through the susceptor 459. At the top of the lifter pin 413, it is provided a lifter pin holding part 414 for holding the wafer 600.

The lifter pin holding part 414 extends toward the center of the susceptor 459. The rise and fall of the lifter pin 413 allow the wafer 600 to be placed on the susceptor table 411 or to be lifted up from the susceptor table 411.

A lifting shaft 473 of a lifting drive part (not shown) is provided in the bottom substrate 469 and connected to the up-and-down substrate 471. Lifting up and down the up-and-down shaft 473 by the lifting drive part allows the lift pin holding part 414 to be raised and lowered through the up-and-down substrate 471 and the lifter pin 413.

Between the susceptor 459 and the exhausting plate 465, it is provided a cylindrical baffle ring 458. The baffle ring 458, the susceptor 459 and the exhausting plate 465 form a first exhausting chamber 474. The cylindrical baffle ring 458 is provided on its cylindrical side surface with a number of air holes evenly. Accordingly, the first exhausting chamber 474 is separated from the treating chamber 445 and communicates with the treating chamber through the air holes.

An exhausting communication hole 475 is provided at the center of the exhausting plate 465. The first exhausting chamber communicates with a second exhausting chamber 476 through the exhausting communication hole 475. The second exhausting chamber 476 communicates with an exhausting tube 480. The exhausting tube 480 is provided with an exhausting apparatus 479.

The top plate 454 located on an upper part of the reaction case 431 is provided with a gas supplying tube 455 which extends from a gas supplying equipment (not shown) and supplies the required reaction gas for the plasma. The gas supplying tube 455 is attached to the gas introduction port 433. The gas supplying tube 455 is provided with a mass flow controller 477 and an opening and closing valve 478, which form a flow rate control part. Controlling the mass flow controller 477 and the opening and closing valve 478 allows the quantity of supply of the gas to be controlled.

Further, in the reaction case 431, it is provided a substantially disk-shaped baffle plate 460 made of quarts in order to let the reaction gas flow along the inner wall of the reaction case 431.

The pressure in the treating chamber is adjusted with adjusting the quantity of supply and displacement by the flow late part and the exhaust apparatus.

The winding diameter, the winding pitch and the number of winding of the resonance coil 432 are set so that resonance would be achieved at a fixed wavelength mode for the purpose of forming a standing wave with a predetermined wavelength. That is to say, the electric length of the resonance coil 432 is set to be equivalent to an integral multiple (one, two . . . ), half or one-fourth of one wavelength in a predetermined frequency of the power supplied from the high frequency power source 444.

The length of one wavelength is around 22 meters in the case of 13.56 MHz, around 11 meters in the case of 27.12 MHz and around 5.5 meters in the case of 54.24 MHz, for example.

The height of the plasma generating chamber 430 increases when the coil is set at one wavelength. This allows the time for forming the treating gas into the plasma to be elongated, so that forming the gas into the plasma is certainly facilitated as a result. Further, the coil per se is short in the case of the half or one-fourth wavelength instead of one wavelength. This brings an advantage that the height of the plasma treating chamber is lower than the case of one wavelength.

Concretely, in view of the power to be applied, the strength of a magnetic field to be generated or an external shape of the apparatus to be applied, the resonance coil 432 is arranged so that the area of its effective cross-section would be 50 to 300 mm², its diameter would be 200 to 500 mm and the number of windings around the outer circumference of the reaction case 431 would be about 2 to 60, in order to be able to generate a magnetic field of around 0.01 to 10 gausses with high frequency power of 800 kHz to 50 MHz and 0.5 to 5 KW, for example. As a material of the resonance coil 432, used is a copper pipe, a copper thin plate, an aluminum pipe, an aluminum thin plate, a polymer belt having copper or aluminum deposited thereon or the like. The resonance coil 432 is held on plural supports, which are formed from an insulating material in the shape of a flat plate and erected vertically to an upper end surface of the base plate 448.

The both ends of the resonance coil 432 are electrically grounded. At least one end of the resonance coil 432, however, is grounded through a movable tap 462 in order to carry out fine adjustment of the electrical length of the resonance coil in first installation of the apparatus or in changing a condition of treatment. Numeral 464 in FIG. 4 denotes the other fixed ground. Furthermore, a power supplying part is formed from the movable tap 466 between the both grounded ends of the resonance coil 432 in order to make fine adjustment of impedance of the resonance coil 432 in first installation of the apparatus or in changing a condition of treatment.

That is to say, the resonance coil 432 is provided at its both ends with electrically grounded ground parts and provided with a power supplying part supplied with the power from the high frequency power source 444 between the respective ground parts. Moreover, at least one ground part is a variable ground part capable of adjustment in position and the power supplying part is a variable power supplying part capable of adjustment in position. In the case that the resonance coil 432 includes the variable ground part and the variable power supplying part, the resonance frequency and the load impedance in the plasma generating chamber 430 can be further easily adjusted as described later.

Further, at one end (on the other end or the both ends) of the resonance coil 432, inserted may be a waveform adjusting circuit formed from a coil and a shield so that phase and opposite phase currents would flow symmetrically with respect to an electrically middle point of the resonance coil 432. The waveform adjusting circuit is formed into an open circuit by setting the ends of the resonance coil 432 to be electrically unconnected or to be electrically equivalent. The ends of the resonance coil 432 may be made ungrounded by choke series resistor to be connected to a fixed standard potential in series.

The outer shield 452 is provided for shielding leakage of an electromagnetic wave toward the outside of the resonance coil 432 as well as forming a capacity component necessary to form a resonance circuit between the outer shield 452 and the resonance coil 432. The outer shield 452 is typically formed from a conductive material such as an aluminum alloy, copper, or a copper alloy in the shape of a cylinder. The outer shield 452 is provided at an interval of around 5 to 150 mm, for example, from the outer circumference of the resonance coil 432. The outer shield 452 is generally grounded so as to be equal in potential to the both ends of the resonance coil 432. For the purpose of precisely setting the number of resonance of the resonance coil 432, however, one or both of the ends of the outer shield 452 may be arranged so that a tap position would be adjustable or a trimming capacitance may be inserted between the resonance coil 432 and the outer shield 452.

The above-mentioned treating chamber 445 for containing the wafer 600 is formed into the shape of a substantial short axis cylinder with a bottom, for example. In the treating chamber 445, it is provided the above-mentioned susceptor table 411, which horizontally holds the wafer 600 and which is in the shape of a short axis column. The susceptor table 411 may be provided with a generally used electrostatic chuck.

As the high frequency power source 444, it may be used an appropriate power source such as an Rf generator so long as the power source can supply the resonance coil 432 with the power having necessary voltage and frequency. For example, it may be used a high frequency generator capable of supplying the power of around 0.5 to 5 KW at the frequency of 80 kHz to 800 MHz.

Moreover, on an output side of the high frequency power source 444, it is provided a reflected wave wattmeter 468. The reflected wave power detected by the reflected wave wattmeter 468 is inputted to a controller 470 used as a control part. The controller 470 controls not only the high frequency power source 444 but also the apparatus for removing photoresist 10 as a whole. The controller 470 is connected to a display 472 used as a display part. The display 472 displays data, which is detected by the various kinds of detecting parts provided in the apparatus for removing photoresist 10, such as a result of detection of the reflected wave by the reflected wave wattmeter 468, for example. The controller 470 not only detects the reflected wave power but also controls the respective parts.

In the apparatus for removing photoresist 10 having such a structure, the wafer 600 is carried to the load lock chamber 250 (260), the load lock chamber 250 (260) is evacuated (vacuum displacement), the wafer 600 is carried from the load lock chamber 250 (260) to the process chamber 410 (420) through the transfer module 310, a photoresist is removed from the wafer 600 in the process chamber 410 (420) (the removing process) and the wafer 600 having the photoresist removed therefrom is again carried to the lock chamber 250 (260) through the transfer module 310.

The removal of the photoresist in the process chamber 410 (420) is a process of removing a photoresist used as a mask in an ion implantation process for the wafer 600, which is a preceding process in the substrate treatment. The photoresist removed in the removing process is arranged to be a double layer of a deteriorated layer and a bulk layer. This is likely to cause a popping phenomenon in which the pressure of a vaporized bulk layer causes an explosion of a deteriorated layer when the temperature reaches a certain value (120 to 160° C., although it depends on a material of the photoresist). Accordingly, the photoresist is oxidized and removed by the O₂ gas, the H₂ gas, the N₂ gas and the mixed gas of the reaction gases with the temperature of the wafer 600 being controlled to be low. Here, the H₂ gas is used after it is mixed in advance with the N₂ gas so as to be of the concentration less than 5%. This allows the H₂ gas to be treated as an inertia gas, so that the equipment can be simplified.

Furthermore, the removal of the photoresist (the removing process) is specifically carried out through a process of placing the wafer 600 on the lifter pin 413 in the process chamber 410 (420), a first removing process performed following the placing process and a second removing process performed following the first removing process. The placing process, the first removing process and the second removing process will be described hereinafter.

Now, it will be described the placing process.

The finger 321 on which the wafer 600 is mounted enters the treating chamber 445. The lifter pin 413 rises at the same time. The finger 321 places the wafer 600 on the raised lifter pin 413. The temperature of the wafer 600 at that time is kept at a room temperature (around 25 degrees) since the wafer 600 is vacuum-insulated in heat from the substrate heating part.

Now, it will be described the first removing process.

After the wafer 600, which is kept at the room temperature, is placed in the transfer process, it is supplied the plasma generating chamber 430 with the N₂H₂ gas and the O₂ gas through the gas supplying tube 433. The N₂H₂ gas may be mixed with the O₂ gas in advance or in the plasma generating chamber 430. In the case of mixing in the plasma generating chamber 430, the gas supplying tube is provided in the number of types of the gas (two, in the embodiment). The high frequency power source 444 supplies the resonance coil 432 with power at that time. Accelerating a free electron by an induction field excited in the resonance coil 432 to make a collision with a gas molecule causes the gas molecules to be excited, and thereby, the plasma to be generated.

The supplied N₂H₂ gas and the O₂ gas are transmuted plasma state.

The plasma is excited after the gas is supplied in the embodiment. The invention, however, is not limited to the above. The high frequency power source 444 may supply the resonance coil with power to form a magnetic field in advance before the gas is supplied.

The substrate heating part 463 gradually heats the wafer 600 to 200° C. in forming the plasma. This is because rapidly heating the wafer is likely to cause a popping phenomenon. Accordingly, the wafer temperature is gradually raised until a surface of the photoresist is removed to a certain degree.

The plasma state of gas mainly removes organic components included in the photoresist. As the reaction gas used in the first plasma forming process, used is the reaction gas formed by mixing the O₂ gas, the N₂ gas and the H₂ gas. The flow ratio of the O₂, the N₂and the H₂ is set at 3000:1000:40, for example.

The flow rate of the gas is controlled by means of the flow rate control part.

The treating pressure is adjusted to be between 1 Torr and 3 Torr.

The O₂ gas is mainly used for removing the photoresist. The H₂ gas is used for suppressing the popping phenomenon. The N₂ gas is used as a diluting gas of the H₂ gas. That is to say, in the first plasma forming process, active species (O radical, chiefly) obtained by electric discharge of the reaction gas with high frequency let the organic component in the photoresist react with oxygen to generate a volatile component such as CO or CO₂, which is discharged as a gas. The flow ratio of the O₂ gas is preferably 10% or more in the first removing process. The flow ratio of the O₂ gas of 10% or more allows the photoresist to be removed at high speed.

In the first removing process, the organic component in the photoresist is removed but dopant remains since the combining power between O₂ and the dopant such as P (phosphorus) As (arsenic) and B (boron) is strong and the dopant does not evaporate even after the combination. That is to say, the dopant implanted in the photoresist and an oxide of the dopant are deposited on a surface of the wafer 600 and not removed in the first removing process.

Now, described will be the second removing process.

The second removing process is a process in which a reduction property of H is used to perform a removal of dopant deposited on the surface of the wafer 600.

In the reaction gas used in the second removing process, it is assumed that the mixing ratio of O₂ is 0% and the flow ratio of the O₂ gas, the N₂ gas and the H₂ gas is 0:1000:40. The treating pressure is set to be lower than in the first removing process, 1.5 Torr, for example.

In the second removing process, the H₂ gas is used for removing the residue while the N₂ gas is used as a diluting gas of the H₂ gas.

In the first removing process, supplied is the O₂ gas. The flow rate control part, however, stops the supply of the O₂ gas and the N₂H₂ gas is supplied to the plasma generating chamber 430 only through the gas supplying tube 433.

At the same time, the lifter pin 413 is lowered. The wafer 600 is approached to the substrate heating part 463 to raise the temperature of the wafer. The temperature of the wafer is raised to 250° C., for example.

Active species mainly formed from H radicals, which are obtained by electric discharge of the mixture gas of the reaction gases with high frequency, are used to gasify the deposition of the dopant on the surface of the wafer 600 as volatile components such as PH₃, AsH₃, and B₂H₆ to discharge and remove the gas in the second removing process.

It is now assumed that O₂ is mixed in the reaction gas used in the second removing process. For example, it may be considered that the O₂ gas at the first stage remains in the plasma generating chamber 430 and mixes in the N₂H₂ gas supplied in the second removing process.

The reduction of the H radicals due to oxidation reaction and obstruction of a reaction between the H radicals and the dopant decrease the effect of removing the deposition. Accordingly, the mixing ratio of O₂ is to be indispensably 10% or less. The lower the mixing ratio of O₂ is, the more the dopant is removed. That is to say, the less the mixing quantity of the O₂ gas is, the more the removal rate of the residue due to the reducing reaction of the hydrogen radical H increases.

On the other hand, using only the H₂ gas and the N₂ gas to generate the plasma causes Na to be generated while using the O₂ gas can suppress Na generated from the reaction case 431 made of quartz. Accordingly, mixing a fixed quantity of oxygen is effective to reduce Na contamination.

In this case, the flow rate control part controls the quantity of supply of the O₂ gas so that O₂ would be 10% or less instead of stopping the supply of the O₂ gas, in the second removing process.

The O₂ gas is not necessary when the quality of the reaction case 431 made of quarts is excellent, of course, since generation of Na is suppressed.

In view of the above, it is desirable to decide the flow ratio of oxygen at 0 to 10%, which is the range capable of coping with both of the peeling off the residue and the reduction of Na contamination, taking into account the quality of the reaction case 431. NH₃ can be substituted for H₂. An inertia gas such as He and Ar can be substituted for N₂.

In the first removing process and the second removing process, which are described above, the flow rate of the gas is changed, and the mixing ratio of the gas and the pressure is changed. Accordingly, the load impedance of the high frequency power source 444 fluctuates. The oscillation frequency of the high frequency power source 444, however, can be matched quickly in response to the change in temperature of treatment or in pressure since the frequency matching unit 446 is provided.

Further, in the apparatus for removing photoresist 10 described above, the frequency matching unit 446 controls the spiral resonator so that the reflected wave power would be the smallest when the oscillation frequencies of the resonance coil 432 and the spiral resonator formed from the resonance coil 432 are changed from the first removing process to the second removing process.

Concretely, the following operations are carried out.

In forming the plasma in the first removing process, the plasma is converged into the resonance frequency of the resonance coil 432. The reflected wave wattmeter 468 detects the reflected wave from the resonance coil 432 at that time to send the detected level of the reflected wave to the frequency matching unit 446. The frequency matching unit 446 adjusts the oscillation frequency of the high frequency power source 444 so that the reflected wave of the reflected wave power would be the smallest. The oscillation frequency is preferably obtained in advance on the basis of an experiment. In the case of the embodiment, the data (the level of the reflected wave and oscillation frequency data for achieving the smallest level of the reflected wave, for example) is stored in the controller 470 and the detected reflected wave is compared with the data so as to determine the oscillation frequency for the convergence on the basis of an error of the data or the like.

The reflected wave is ideally controlled to be the smallest in each apparatus. In the case of controlling plural apparatus respectively, however, it is considered that a control method is unified, that is, common software is used for control. In this case, a difference between the apparatus in oscillation frequency with which the reflected wave is smallest occurs in some cases. Accordingly, an average of the values with which the reflected wave becomes smallest in the respective apparatus may be obtained in advance to be used for convergence.

The flow rate control part controls the flow rate so that the supply of O₂ would be stopped or be 10% or less in the second removing process. The supply of power from the high frequency power source is continued from the first stage and the electrical discharge state is maintained.

At that time, the flow rate of the gas, the mixing ratio of the gas or the pressure in the treating chamber 445 fluctuates in some cases, compared with the case of the first removing process. This largely changes the ionization property of the gas molecule and the resonance frequency of the resonance coil 432 fluctuates in accordance with the change, so that the reflected wave is temporarily increased. The reflected wave wattmeter 468 detects the reflected wave outputted from the resonance coil 432 to send the detected level of the reflected wave to the frequency matching unit 446. The frequency matching unit 446 adjusts the oscillation frequency of the high frequency power source 444 so that the reflected wave of the reflected wave power would be the smallest. The oscillation frequency is preferably obtained in advance on the basis of an experiment. In that case, the data (the level of the reflected wave and oscillation frequency data for achieving the smallest level of the reflected wave, for example) is stored in the controller 470 and the detected reflected wave is compared with the data so as to determine the oscillation frequency for the convergence on the basis of an error of the data and the like.

The oscillation frequency with which the reflected wave becomes the smallest in each apparatus may be outputted, similarly to the case of the first removing process, however, the oscillation frequency, which is an average value of plural apparatus may be also outputted.

As described above, carrying out continuous control by the controller allows the processes to be continuously carried out without losing the plasma or requiring re-ignition when shifting from the first removing process to the second removing process.

Now, described will be a apparatus provided with no frequency matching unit 446 and no reflected wave wattmeter 468, as a comparative example with the above.

The photoresist is removed in the first removing process. Supply of power from the high frequency power source 444 is suspended once after the photoresist is removed. Following the suspension of power, the flow rate control part and the pressure control part are controlled to reset the pressure and the flow rate of the gas in the treating chamber 445.

In the second removing process, H₂N₂ is supplied to the plasma generating chamber 430 to remove the residue.

As described above, electric discharge causes a fire to be lost when shifting from the first removing process to the second removing process, so that re-ignition is required in the second removing process as a result. This results in requirement of time for re-ignition.

Using the frequency matching unit 446 and the reflected wave wattmeter 468 like the operation of the invention allows a loss of time such as the time for re-ignition to be omitted, so that throughput can be improved.

The invention is characterized by matters described in Claims and also includes the following matters.

(1) A method of manufacturing a semiconductor device comprising a process for removing from a substrate a photoresist to which a high dose of ion has been implanted, wherein

the removing process including the following processes: a first removing process for carrying out a plasma process of a reaction gas including at least oxygen molecules and hydrogen molecules to remove an organic component in the photoresist from the substrate; and

a second removing process for carrying out a plasma process of a reaction gas including at least hydrogen molecules following the first removing process to remove a dopant deposit from the substrate.

(2) The method of manufacturing a semiconductor device according to (1), wherein the second removing process is for carrying out a plasma process of a reaction gas including oxygen.

(3) The method of manufacturing a semiconductor device according to (1), wherein the second removing process is for carrying out a plasma process of a reaction gas including oxygen of 10% or less.

(4) The method of manufacturing a semiconductor device according to any one of (1) to (3), wherein a reaction gas including oxygen molecules and a hydrogen gas with a diluted gas added are supplied in the first removing process.

(5) A method of manufacturing a semiconductor device comprising a process for removing from a substrate a photoresist with a high dose of ion implanted, wherein

the removing process includes single or plural processes and carries out a plasma process of a reaction gas including a hydrogen component with a diluted gas added in a process immediately before completion of the removal of the photoresist to remove a residue from the substrate.

(6) A substrate processing apparatus comprising:

a reaction case which is arranged to be capable of reduction in pressure;

a treating chamber which is provided continuously to the reaction case and in which a substrate whose photoresist is to be removed is accommodated;

a reaction gas supplying part which supplies the reaction case with a reaction gas;

a flow rate control part which controls a flow rate of the reaction gas supplied from the reaction gas supplying part; and

a supply control part which controls at least the reaction gas supplying part so that it supplies the reaction case with a reaction gas including at least oxygen molecules and hydrogen molecules to carry out a plasma process in the reaction case as a first stage and supplies the reaction case with a reaction gas including at least hydrogen molecules to carry out a plasma process in the reaction case as a second stage.

(7) A substrate processing apparatus comprising:

a reaction case which is arranged to be capable of reduction in pressure;

a spiral resonator including a resonance coil wound around the outer circumference of the reaction case and an outer shield provided in the outer circumference of the resonance coil and electrically grounded;

a treating chamber which is provided continuously to the reaction case and in which a substrate whose photoresist is to be removed is accommodated;

a high frequency power source which supplies the resonance coil with high frequency power having a predetermined frequency;

a reaction gas supplying part which supplies the reaction case with a reaction gas;

a flow rate control part which controls a flow rate of the reaction gas supplied from the reaction gas supplying part;

a supply control part which controls at least the reaction gas supplying part so that supplies the reaction case with a reaction gas including at least oxygen molecules and hydrogen molecules to carry out a plasma process in the reaction case as a first stage and supplies the reaction case with a reaction gas including at least hydrogen molecules to carry out a plasma process in the reaction case as a second stage; and

a frequency control part which controls an oscillation frequency of the high frequency power source so that reflected power from the spiral resonator would be the smallest in the change from the first stage to the second stage.

(8) An in-situ processing method comprising a process for removing from a substrate a photoresist with a high dose of ion implanted, wherein

the removing process including the following processes: a first removing process for forming a reaction gas including at least oxygen molecules and hydrogen molecules into a plasma to remove an organic component in the photoresist from the substrate; and

a second removing process for carrying out a plasma process of a reaction gas including at least hydrogen molecules following the first removing process to remove a dopant deposit from the substrate.

(9) An in-situ processing apparatus comprising:

a reaction case which is arranged to be capable of reduction in pressure;

a spiral resonator which includes a resonance coil wound around the outer circumference of the reaction case and an outer shield provided in the outer circumference of the resonance coil and electrically grounded;

a treating chamber which is provided continuously to the reaction case and in which a substrate whose photoresist is to be removed is accommodated;

a high frequency power source which supplies the resonance coil with high frequency power having a predetermined frequency;

a reaction gas supplying part which supplies the reaction case with a reaction gas;

a flow rate control part which controls the flow rate of the reaction gas supplied from the reaction gas supplying part; and

a supply control part which controls at least the reaction gas supplying part so that it supplies the reaction case with a reaction gas including at least oxygen molecules and hydrogen molecules to carry out a plasma process in the reaction case as a first stage and supplies the reaction case with a reaction gas including at least hydrogen molecules to carry out plasma process in the reaction case as a second stage.

(10) A method of supplying a reaction gas, comprising the processes of:

a first supplying process for supplying a reaction case provided continuously to a treating chamber for accommodating a substrate having a high dose of ion implanted therein with at least a reaction gas including oxygen molecules and a reaction gas including hydrogen molecules; and

a second supplying process for stopping the supply of the reaction case with the reaction gas including the oxygen component while continuously supplying the reaction case with the reaction gas including the hydrogen component after a plasma process for the reaction gas including oxygen molecules and the reaction gas including hydrogen molecules is carried out in the reaction case.

(11) A reaction gas supplying apparatus comprising:

a reaction gas supplying part which supplies a reaction case provided continuously to a treating chamber for accommodating a substrate having a high dose of ion implanted therein with a reaction gas; and

a reaction gas supply control part which controls the reaction gas supplying part so that it supplies the reaction case with at least a reaction gas including oxygen molecules and a reaction gas including hydrogen molecules and stops the supply of the reaction case with the reaction gas including the oxygen component while continuously supplying the reaction case with the reaction gas including the hydrogen component after a plasma process for the reaction gas including oxygen molecules and the reaction gas including hydrogen molecules is carried out in the reaction case.

As described above, the invention is applicable to a method of manufacturing a semiconductor device, which includes a process of removing a photoresist from a substrate.

1. A method of manufacturing a semiconductor device comprising a process for removing from a substrate a photoresist with a high dose of ion implanted, wherein
the removing process including the following processes: a first removing process for carrying out a plasma process of a reaction gas including at least oxygen molecules and hydrogen molecules to remove an organic component in the photoresist from the substrate; and
a second removing process for carrying out a plasma process of a reaction gas including at least hydrogen molecules following the first removing process to remove a dopant deposit from the substrate.

2. The method of manufacturing a semiconductor device according to claim 1, wherein the second removing process is for carrying out a plasma process of a reaction gas including oxygen.

3. The method of manufacturing a semiconductor device according to claim 1, wherein the second removing process is for carrying out a plasma process of a reaction gas including 10% or less of oxygen.

4. The method of manufacturing a semiconductor device according to claim 1, wherein a reaction gas including oxygen molecules and a hydrogen gas with a diluted gas added are supplied in the first removing process.

5. A method of manufacturing a semiconductor device comprising a process for removing from a substrate a photoresist with a high dose of ion implanted, wherein
the removing process includes single or plural processes and carries out a plasma process of a reaction gas including a hydrogen component with a diluted gas added in a process immediately before completion of the removal of the photoresist to remove a residue from the substrate.

6. A substrate processing apparatus comprising:
a reaction case which is arranged to be capable of reduction in pressure;
a treating chamber which is provided continuously to the reaction case and in which a substrate whose photoresist is to be removed is accommodated;
a reaction gas supplying part which supplies the reaction case with a reaction gas;
a flow rate control part which controls a flow rate of the reaction gas supplied from the reaction gas supplying part; and
a supply control part which controls at least the reaction gas supplying part so that it supplies the reaction case with a reaction gas including at least oxygen molecules and hydrogen molecules to carry out a plasma process in the reaction case as a first stage and supplies the reaction case with a reaction gas including at least hydrogen molecules to carry out a plasma process in the reaction case as a second stage.

7. A substrate processing apparatus comprising:
a reaction case which is arranged to be capable of reduction in pressure;
a spiral resonator including a resonance coil wound around the outer circumference of the reaction case and an outer shield provided in the outer circumference of the resonance coil and electrically grounded;
a treating chamber which is provided continuously to the reaction case and in which a substrate whose photoresist is to be removed is accommodated;
a high frequency power source which supplies the resonance coil with high frequency power having a predetermined frequency;
a reaction gas supplying part which supplies the reaction case with a reaction gas;
a flow rate control part which controls a flow rate of the reaction gas supplied from the reaction gas supplying part;
a supply control part which controls at least the reaction gas supplying part so that it supplies the reaction case with a reaction gas including at least oxygen molecules and hydrogen molecules to carry out a plasma process in the reaction case as a first stage and supplies the reaction case with a reaction gas including at least hydrogen molecules to carry out a plasma process in the reaction case as a second stage; and
a frequency control part which controls an oscillation frequency of the high frequency power source so that reflected power from the spiral resonator would be the smallest in the change from the first stage to the second stage.

8. An in-situ processing method comprising a process for removing from a substrate a photoresist with a high dose of ion implanted, wherein
the removing process including the following processes: a first removing process for forming a reaction gas including at least oxygen molecules and hydrogen molecules into a plasma to remove an organic component in the photoresist from the substrate; and
a second removing process for carrying out a plasma process of a reaction gas including at least hydrogen molecules following the first removing process to remove a dopant deposit from the substrate.

9. An in-situ processing apparatus comprising:
a reaction case which is arranged to be capable of reduction in pressure;
a spiral resonator which includes a resonance coil wound around the outer circumference of the reaction case and an outer shield provided in the outer circumference of the resonance coil and electrically grounded;
a treating chamber which is provided continuously to the reaction case and in which a substrate whose photoresist is to be removed is accommodated;
a high frequency power source which supplies the resonance coil with high frequency power having a predetermined frequency;
a reaction gas supplying part which supplies the reaction case with a reaction gas;
a flow rate control part which controls the flow rate of the reaction gas supplied from the reaction gas supplying part; and
a supply control part which controls at least the reaction gas supplying part so that it supplies the reaction case with a reaction gas including at least oxygen molecules and hydrogen molecules to carry out a plasma process in the reaction case as a first stage and supplies the reaction case with a reaction gas including at least hydrogen molecules to carry out plasma process in the reaction case as a second stage.

10. A method of supplying a reaction gas, comprising the processes of:
a first supplying process for supplying a reaction case provided continuously to a treating chamber for accommodating a substrate having a high dose of ion implanted therein with at least a reaction gas including oxygen molecules and a reaction gas including hydrogen molecules; and
a second supplying process for stopping the supply of the reaction case with the reaction gas including the oxygen component while continuously supplying the reaction case with the reaction gas including the hydrogen component after a plasma process for the reaction gas including oxygen molecules and the reaction gas including hydrogen molecules is carried out in the reaction case.

11. A reaction gas supplying apparatus comprising:
a reaction gas supplying part which supplies a reaction case provided continuously to a treating chamber for accommodating a substrate having a high dose of ion implanted therein with a reaction gas; and
a reaction gas supply control part which controls the reaction gas supplying part so that it supplies the reaction case with at least a reaction gas including oxygen molecules and a reaction gas including hydrogen molecules and stops the supply of the reaction case with the reaction gas including the oxygen component while continuously supplying the reaction case with the reaction gas including the hydrogen component after a plasma process of the reaction gas including oxygen molecules and the reaction gas including hydrogen molecules is carried out in the reaction case.

12. The method of manufacturing a semiconductor device according to claim 2, wherein a reaction gas including oxygen molecules and a hydrogen gas with a diluted gas added are supplied in the first removing process.

13. The method of manufacturing a semiconductor device according to claim 3, wherein a reaction gas including oxygen molecules and a hydrogen gas with a diluted gas added are supplied in the first removing process.
